(19) United States
(12) Patent Application Publication
(10) Pub. No.: US 2007/0007510 A1
(43) Pub. Date: Jan. 11, 2007

(54) Stackable memory device and organic transistor structure

(75) Inventors: Igor Sokolik, East Boston, MA (US); Suzette K. Pangrle, Cupertino, CA (US); Juri Krieger, Brookline, MA (US)

Correspondence Address: Paul J. Winters, 307 Cypress Point drive, Mountain View, CA, 94043, US

(73) Assignee: Spansion LLC

(21) Appl. No.: 11/174,881

(22) Filed: Jul. 5, 2005

(51) Int. Cl. H01L 29/08

(52) U.S. Cl. 257/40

(57) ABSTRACT

In the present electronic structure, a first electronic device includes a first pair of electrodes and an active layer between the first pair of electrodes. An organic transistor is made up of organic material, a source, a drain, and a gate, one of the first pair of electrodes being connected to one of the source and drain of the organic transistor. A second electronic device includes a second pair of electrodes and an active layer between the second pair of electrodes, one of the second pair of electrodes being in contact with an insulating body adjacent the organic transistor.

### BACKGROUND OF THE INVENTION

1. Technical Field

This invention relates generally to electronic structures, and more particularly, to an electronic structure combining memory devices and transistors.

2. Background Art

The volume, use and complexity of computers and electronic devices are continually increasing. Computers consistently become more powerful, new and improved electronic devices are continually developed (e.g., digital audio players, video players). Additionally, the growth and use of digital media (e.g., digital audio, video, images, and the like) have further pushed development of these devices. Such growth and development has vastly increased the amount of information desired/required to be stored and maintained for computer and electronic devices.

Generally, information is stored and maintained in one or more of a number of types of storage devices. Storage devices include long term storage mediums such as, for example, hard disk drives, compact disk drives and corresponding media, digital video disk (DVD) drives, and the like. The long term storage mediums typically store larger amounts of information at a lower cost, but are slower than other types of storage devices. Storage devices also include memory devices, which are often, but not always, short term storage mediums. Memory devices tend to be substantially faster than long term storage mediums. Such memory devices include, for example, dynamic random access memory (DRAM), static random access memory (SRAM), double data rate memory (DDR), flash memory, read only memory (ROM), and the like. Memory devices are subdivided into volatile and non-volatile types. Volatile memory devices generally lose their information if they lose power and typically require periodic refresh cycles to maintain their information. Volatile memory devices include, for example, random access memory (RAM), DRAM, SRAM and the like. Non-volatile memory devices maintain their information whether or not power is maintained to the devices. Non-volatile memory devices include, but are not limited to, ROM, programmable read only memory (PROM), erasable programmable read only memory (EPROM), flash memory and the like. Volatile memory devices generally provide faster operation at a lower cost as compared to non-volatile memory devices.

Memory devices generally include arrays of memory devices. Each memory device can be accessed or “read”, “written”, and “erased” with information. The memory devices maintain information in an “off” or an “on” state, also referred to as “0” and “1”. Typically, a memory device is addressed to retrieve a specified number of byte(s) (e.g., 8 memory devices per byte). For volatile memory devices, the memory devices must be periodically “refreshed” in order to maintain their state. Such memory devices are usually fabricated from semiconductor devices that perform these various functions and are capable of switching and maintaining the two states. The devices are often fabricated with inorganic solid state technology, such as, crystalline silicon devices. A common semiconductor device employed in memory devices is the metal oxide semiconductor field effect transistor (MOSFET).

The use of portable computer and electronic devices has greatly increased demand for non-volatile memory devices. Digital cameras, digital audio players, personal digital assistants, and the like generally seek to employ large capacity non-volatile memory devices (e.g., flash memory, smart media, compact flash, and the like).

Because of the increasing demand for information storage, memory device developers and manufacturers are constantly attempting to increase storage capacity for memory devices (e.g., increase storage per die or chip). A postage-stamp-sized piece of silicon may contain tens of millions of transistors, each transistor as small as a few hundred nanometers. However, silicon-based devices are approaching their fundamental physical size limits. Inorganic solid state devices are generally encumbered with a complex architecture which leads to high cost and a loss of data storage density. The volatile semiconductor memories based on inorganic semiconductor material must constantly be supplied with electric current with a resulting heating and high electric power consumption in order to maintain stored information. Non-volatile semiconductor devices have a reduced data rate and relatively high power consumption and large degree of complexity. Typically, fabrication processes for such cells are also not reliable.

Therefore, there is a need to overcome the aforementioned deficiencies.

FIG. 1 illustrates a type of memory device 30, which includes advantageous characteristics for meeting these needs. The memory device 30 includes an electrode 32 (for example copper), a copper sulfide layer 34 on the electrode 32, an active layer 36, for example a copper oxide layer, on the layer 34, and an electrode 38 (for example titanium) on the active layer 36. Initially, assuming that the memory device 30 is unprogrammed, in order to program the memory device 30, ground is applied to the electrode 38, while a positive voltage is applied to electrode 32, so that an electrical potential V_{pg} (the “programming” electrical potential) is applied across the memory device 30 from a higher to a lower electrical potential in the forward direction of the memory device 30 (see FIG. 2, a plot of memory device current vs. electrical potential applied across the memory device 30). This potential is sufficient to cause copper ions to be attracted from the layer 34 toward the electrode 38 and into the active layer 36 (A) so that conductive filaments are formed, causing the active layer 36 (and the overall memory device 30) to be in a (forward) low-resistance or conductive state. Upon removal of such potential (B), the ions drawn into the active layer 36 during the programming step remain therein, so that the active layer 36 (and memory device 30) remain in a conductive or low-resistance state.

In the read step of the memory device 30 in its programmed (conductive) state, an electrical potential Vᵣ (the “read” electrical potential) is applied across the memory device 30 from a higher to a lower electrical potential in the forward direction of the memory device 30. This electrical potential is less than the electrical potential V_{pg} applied across the memory device 30 for programming (see above). In this situation, the memory device 30 will readily conduct current, which indicates that the memory device 30 is in its programmed state.

In order to erase the memory device, a positive voltage is applied to the electrode 38, while the electrode 32 is held at ground, so that an electrical potential Vₑᵣ (the “erase” electrical potential) is applied across the memory device 30 from a higher to a lower electrical potential in the reverse direction of the memory device 30. This potential is sufficient to cause copper ions to be repelled from the active layer 36 toward the electrode 32 and into the layer 34 (C), causing the active layer 36 (and the overall memory device 30) to be in a high-resistance or substantially non-conductive state. This state remains upon removal of such potential from the memory device 30.

In the read step of the memory device 30 in its erased (substantially non-conductive) state, the electrical potential Vᵣ is again applied across the memory device 30 from a higher to a lower electrical potential in the forward direction of the memory device 30, as described above. With the active layer 34 (and memory device 30) in a high-resistance or substantially non-conductive state, the memory device 30 will not conduct significant current, which indicates that the memory device 30 is in its erased state.

The memory device 30 shown and described has been shown to include advantageous characteristics for meeting the needs described above.

In addition, organic transistors, i.e., thin-film transistors with active organic layers, are emerging as an inexpensive alternative to silicon-based transistors for some applications. While providing high performance, such organic-based transistors can be produced using a simpler and less expensive processing as compared to silicon devices, which require relatively complicated processing using expensive processing equipment. In addition, the organic materials may be processed at low temperature and provide greater mechanical flexibility than silicon. An example of such an organic transistor is illustrated in FIG. 3. As shown therein, the transistor 40 includes a substrate 42 on which an organic layer 44 is formed. Metal source 46 and drain 48 are formed in the organic layer 44, and an insulating layer 50 is provided over that structure. A metal gate 52 is formed in the insulating layer 50, spaced from the organic layer 44 between the source 46 and drain 48 by a portion of the insulating layer 50.

An approach for operatively combining memory devices of the type illustrated at 30 with organic transistors of the type illustrated at 40 in the same electronic device would be desirable, as the advantages of each as set forth above can be included in the overall structure. What is needed is an approach wherein such devices are combined in an electronic structure which is properly operative and configured in an efficient design.

### DISCLOSURE OF THE INVENTION

Broadly stated, the present electronic structure comprises a first electronic device comprising a first pair of electrodes and an active layer between the first pair of electrodes, an organic transistor comprising organic material, a source, a drain, and a gate, one of the first pair of electrodes being connected to one of the source and drain of the organic transistor, an insulating body adjacent the organic transistor, and a second electronic device comprising a second pair of electrodes and an active layer between the second pair of electrodes, one of the second pair of electrodes being in contact with the insulating body.

The present invention is better understood upon consideration of the detailed description below, in conjunction with the accompanying drawings. As will become readily apparent to those skilled in the art from the following description, there is shown and described an embodiment of this invention simply by way of the illustration of the best mode to carry out the invention. As will be realized, the invention is capable of other embodiments and its several details are capable of modifications and various obvious aspects, all without departing from the scope of the invention. Accordingly, the drawings and detailed description will be regarded as illustrative in nature and not as restrictive.

### BRIEF DESCRIPTION OF THE DRAWINGS

The novel features believed characteristic of the invention are set forth in the appended claims. The invention itself, however, as well as said preferred mode of use, and further objects and advantages thereof, will best be understood by reference to the following detailed description of an illustrative embodiment when read in conjunction with the accompanying drawings, wherein:

FIG. 1 is a cross-sectional view of an above-described memory device;

FIG. 2 is a plot of current vs. voltage illustrating operating characteristics of the memory device of FIG. 1;

FIG. 3 is a cross-sectional view up a typical organic transistor; and

FIG. 4 is a cross-sectional view illustrating an embodiment of the present invention.

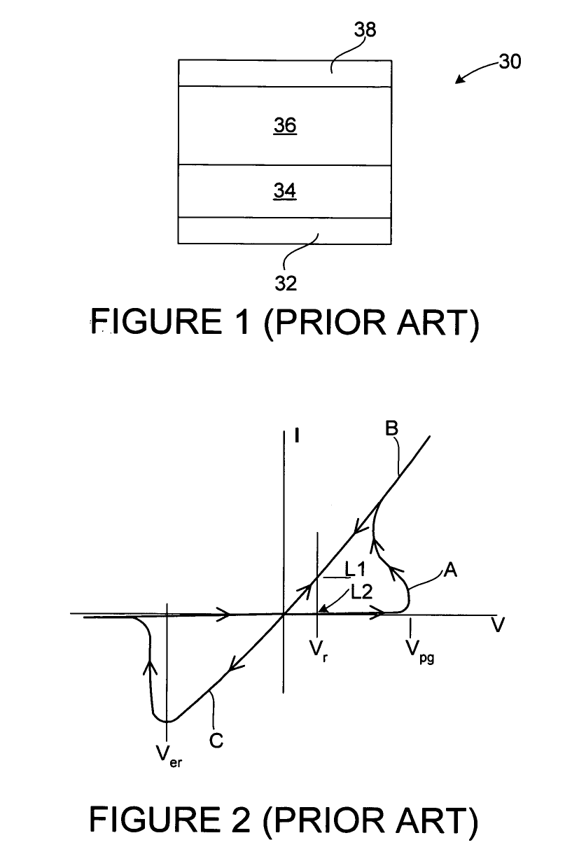

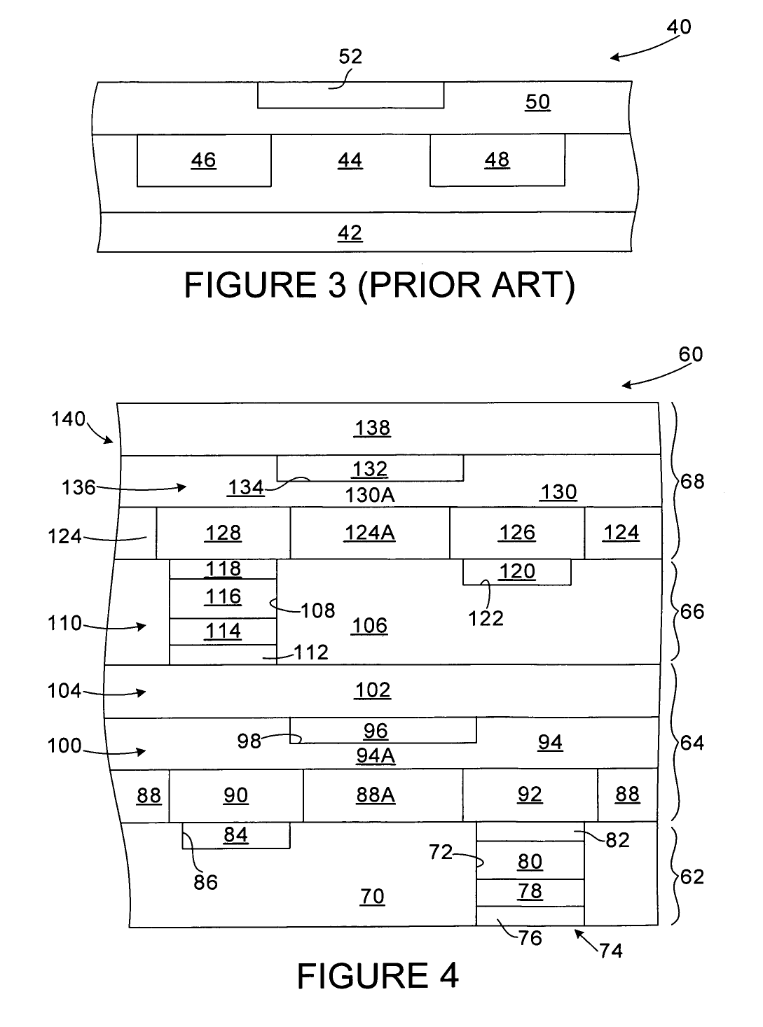

### BEST MODE(S) FOR CARRYING OUT THE INVENTION

Reference is now made in detail to a specific embodiment of the present invention which illustrates the best mode presently contemplated by the inventors for practicing the invention.

FIG. 4 illustrates the present electronic structure 60. The electronic structure is made of a plurality of successively applied device layers 62, 64, 66, 68 which will now be described in detail. Initially, an insulating layer 70 is provided, defining an opening 72 therethrough. A memory device 74 as described above is provided in the opening 72, and includes an electrode 76, a passive layer 78 on and in contact with the electrode 76, an active layer 80 (which may be of organic or inorganic material) on and in contact with the passive layer 78, and an electrode 82 on and in contact with the active layer 80, so that the active and passive layers 80, 78 are between the electrodes 76, 82. The electrodes 76, 82 are positioned at opposite sides of the insulating layer 76 for access thereto. A contact 84 is provided in a recess 86 in the insulating layer 76 on the same side of the insulating layer 76 as the electrode 82. The insulating layer 70, memory device 74, and contact 84 make up part of device layer 62.

An organic layer 88 is formed on and in contact the device layer 62, with a metal source 90 formed in the organic layer 88 on and in contact with the contact 84, and with a metal drain 92 formed in the organic layer 88 on and in contact with the electrode 82. An insulating layer 94 is formed on and in contact with the resulting structure, and a metal gate 96 is formed in a recess 98 in the insulating layer 94, so that a portion 94A of the insulating layer 94 is between the gate 96 and the portion 88A of the organic layer 88 between the source 90 and drain 92. The organic layer 88, source 90, drain 92, insulating layer 94 and gate 96 form an organic transistor 100 as previously shown and described. Another insulating layer 102 is formed on and in contact the resulting structure, the insulating layer 94 and insulating layer 102 forming insulating body 104 adjacent the organic transistor 100. The organic layer 88, source 90, drain 92, gate 96 and insulating body 104 (formed by insulating layers 94, 102) make up part of device layer 64 which is disposed on and in contact with the device layer 62, with the drain 92 of the organic transistor 100 in operative contact with the electrode 82 of the memory device 74.

Next, an insulating layer 106 is formed on and in contact with the insulating layer 102, defining an opening 108 therethrough. A memory device 110 similar to memory device 74 is provided in the opening 108, and includes an electrode 112 on and in contact with the insulating layer 102, a passive layer 114 on and in contact with the electrode 112, an active layer 116 (which may be of organic or inorganic material) on and in contact with the passive layer 114, and an electrode 118 on and in contact with the active layer 116, so that the active and passive layers 116, 114 are between the electrodes 112, 118. A contact 120 is provided in a recess 122 in the insulating layer 106 on the same side of the insulating layer 106 as the electrode 118. The insulating layer 106, memory device 110, and contact 120 make up part of device layer 66.

Similar to the above, an organic layer 124 is formed on and in contact the device layer, with a metal drain 126 formed in the organic layer 124 on and in contact with the contact 120, and with a metal source 128 formed in the organic layer 124 on and in contact with the electrode 118. An insulating layer 130 is formed on and in contact with the resulting structure, and a metal gate 132 is formed in a recess 134 in the insulating layer 130, so that a portion 130A of the insulating layer 130 is between the gate 132 and the portion 124A of the organic layer 124 between the source 128 and drain 126. The organic layer 124, source 128, drain 126, insulating layer 130, and gate 132 form an organic transistor 136 as previously shown and described. Another insulating layer 138 is formed on and in contact the resulting structure, the insulating layer 130 and insulating layer 138 forming insulating body 140 adjacent the organic transistor 136. The organic layer 124, source 128, drain 126, gate 132 and insulating body 140 (made up of insulating layers 130, 138) make up part of the device layer 68 which is disposed on and in contact with the device layer 66, with the source 128 of the organic transistor 136 operatively in contact with the electrode 118 of the memory device 110. The process of adding such device layers can be continued as desired, resulting in an electronic structure with many layers containing organic transistors and many layers containing memory devices, each adjacent pair of layers containing organic transistors being separated by a layer containing memory devices.

It will be understood that each device layer 64, 68 will contain many individual organic transistors, and each device layer 62, 66 will contain many individual memory devices, which may be operatively connected to organic transistors in device layers described and illustrated. Thus, the advantages of providing interconnected memory devices of the type described above along with organic transistors in the same electronic structure are achieved. In addition, with the electronic structure being formed by providing successive layers, an efficient approach to manufacturing such structure with proper connections between memory devices and transistors is achieved.

The foregoing description of the embodiment of the invention has been presented for purposes of illustration and description. It is not intended to be exhaustive or to limit the invention to the precise form disclosed. Other modifications or variations are possible in light of the above teachings.

The embodiment was chosen and described to provide the best illustration of the principles of the invention and its practical application to thereby enable one of ordinary skill of the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled.

What is claimed is:

1. An electronic structure comprising:
an electronic device comprising first and second electrodes and an active layer between the first and second electrodes;
an organic transistor comprising organic material, a source, a drain, and a gate;
one of the source and drain of the organic transistor being connected to one of the first and second electrodes.

2. The electronic structure of claim 1 wherein the electronic device and organic transistor are in layered relationship.

3. The electronic structure of claim 1 wherein the electronic device further comprises a passive layer between the first and second electrodes.

4. The electronic structure of claim 2 wherein the one of the source and drain of the organic transistor is in contact with the one of the first and second electrodes.

5. The electronic structure claim 2 wherein the electronic device is a memory device.

7. The electronic structure of claim 2 wherein the active layer is an organic layer.

8. The electronic structure of claim 2 wherein the active layer is an inorganic layer.

9. An electronic structure comprising
a first electronic device comprising a first pair of electrodes and an active layer between the first pair of electrodes;
an organic transistor comprising organic material, a source, a drain, and a gate;
one of the first pair of electrodes being connected to one of the source and drain of the organic transistor;
an insulating body adjacent the organic transistor; and
a second electronic device comprising a second pair of electrodes and an active layer between the second pair of electrodes;
one of the second pair of electrodes being in contact with the insulating body.

10. The electronic structure of claim 9 wherein the first electronic device, organic transistor, and second electronic device are in layered relationship.

11. The electronic structure of claim 10 wherein the one of the first pair of electrodes is in contact with the one of the source and drain of the organic transistor.

12. The electronic structure of claim 10 wherein the first electronic device further comprises a passive layer between the first pair of electrodes.

13. The electronic structure of claim 10 wherein the second electronic device further comprises a passive layer between the second pair of electrodes.

14. The electronic structural claim 10 wherein the first electronic device further comprises a passive layer between the first pair of electrodes, and the second electronic device further comprises a passive layer between the second pair of electrodes.

15. The electronic structure of claim 14 wherein the first electronic device is a first memory device, and the second electronic devices a second memory device.

16. The electronic structure of claim 9 and further comprising a second organic transistor comprising organic material, a source, a drain and a gate, the other of the second pair of electrodes being connected to one of the source and drain of the second organic transistor.

17. The electronic structure of claim 16 wherein the first-mentioned electronic device, the first-mentioned organic transistor, second electronic device, and second organic transistor are in layered relationship.

18. The electronic structure of claim 17 wherein the one of the first pair of electrodes is in contact with the one of the source and drain of the first organic transistor, and the other of the second pair of electrodes is in contact with the one of the source and drain of the second organic transistor.
